(19) United States
(12) Patent Application Publication
(10) Pub. No.: US 2003/0224572 A1
(43) Pub. Date: Dec. 4, 2003

(54) Flash memory structure having a T-shaped floating gate and its fabricating method

(76) Inventor: Hsiao-Ying Yang, Hsinchu (TW)

Correspondence Address: BRUCE H. TROXELL, SUITE 1404, 5205 LEESBURG PIKE, FALLS CHURCH, VA, 22041, US

(21) Appl. No.: 10/424,862

(22) Filed: Apr. 29, 2003

Related U.S. Application Data
(63) Continuation-in-part of application No. 10/159,015, filed on Jun. 3, 2002, now abandoned.

(51) Int. Cl. H01L 21/4763; H01L 21/3205; H01L 29/788; H01L 21/336

(52) U.S. Cl. 438/257; 438/593; 438/296

(57) ABSTRACT

The present invention discloses a flash memory structure having a T-shaped floating gate and its fabricating method, the fabricating method comprises the steps of: forming a coupling oxide layer, a buffered layer, and a sacrificial layer in sequence on a semiconductor substrate; forming shallow trench isolation (STI); removing the portion of STI and said sacrificial layer so as to form a concave surface on the STI and a proper depth; foaming a conductive layer, patterning said conductive layer so that a T-shaped floating gate is formed from the conductive layer and the buffered layer. The structure of the floating gate has bigger contacting area so that the capacitive coupling ratio thereof is higher than the one of the prior art, and the electrical property of the flash memory is extremely increased. The buffered layer and said conductive layer are made of a material selected from the group consisting of polysilicon, silicide and amorphous silicon wherein the buffered layer is formed to be 200 to 2500 Å in thickness and the conductive layer is formed to be 300 to 3000 Å in thickness.

This application is a continuation-in-part of U.S. patent application Ser. No. 10/159,015 filed on Jun. 03, 2002, and claims the benefit of the priority date of this case under 35 U.S.C. .sctn.120.

### BACKGROUND OF THE INVENTION

1. Field of the Invention

The present invention generally relates to a flash memory structure having a T-shaped floating gate and its fabricating method, and more particularly, to a flash memory structure having a T-shaped floating gate that has high capacitive coupling ratio.

2. Description of the Prior Art

A flash memory has two modes of operations: electrical program and electrical erasure. In general, the basic configuration of flash memory is composed of two major portions: the memory cell array and the peripheral circuit, and the flash memory cell array for data storage is constructed by a plurality of memory cells regularly arranged in an array based on the intersected word lines and bit lines. The peripheral circuit provides the flash memory with functions such as power supply and data processing during operation. Flash memories can be classified according to the gate electrode structures, one is stack-gate memory cell, and the other is split-gate memory cell.

In the prior art, please refer to FIG. 1A to FIG. 1D, in which the structure of high-density stack-gate flash memory is schematically illustrated. As shown in FIG. 1A, a semiconductor substrate 1 is provided, on which a coupling oxide layer 2, a buffered layer 3, and a silicon nitride layer 4 are formed in sequence and the shallow trench isolation 5(STI) is also formed. As shown in FIG. 1B, the portion of shallow trench isolation 5 is removed, and then the coupling oxide layer 2 and the buffered layer 3 are removed in sequence. After that, a poly silicon layer 6 is deposited for conducting, and patterned by standard photolithography process to be as a floating gate 6a, as shown in FIGS. 1C and 1D.

Obviously, in the prior art, after the buffered layer 3 is removed, the poly silicon layer 6 is deposited and patterned to be as a floating gate 6a, and most important, the capacitive coupling capability of the floating gate is totally determined by the contacting area formed on the floating gate that a conductive layer (or dielectric layer) put thereon later. In his case, the contacting area can be expressed by L1+L2+L1′ as shown in FIG. 1D.

### SUMMARY OF THE INVENTION

It is the major object of the present invention to provide a flash memory structure having a T-shaped floating gate that has high capacitive coupling ratio.

It is another object of the present invention to provide a method for fabricating a flash memory structure having a T-shaped floating gate so as to fabricate a flash memory having high capacitive coupling ratio.

In preferred embodiment of this invention, the buffered layer and said conductive layer are made of a material selected from the group consisting of poly silicon, silicide and amorphous silicon wherein the buffered layer is formed to be 200 to 2500 Å in thickness and the conductive layer is formed to be 300 to 3000 Å in thickness.

### BRIEF DESCRIPTION OF THE DRAWINGS

The objects, spirits and advantages of the preferred embodiment of the present invention will be readily understood with reference to the accompanying drawings and detailed descriptions, wherein:

FIG. 1A to FIG. 1D schematically illustrates a structure of a flash memory gate in accordance with the prior art.

FIG. 2A to FIG. 2E schematically illustrates a flash memory structure having a T-shaped floating gate that has high capacitive coupling ratio in accordance with the present invention.

### DETAILED DESCRIPTION OF THE INVENTION

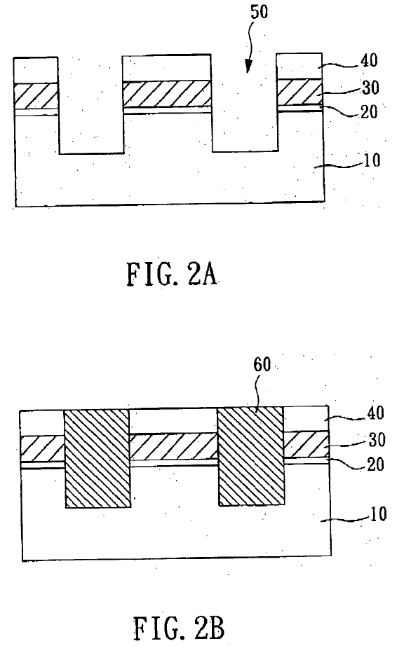

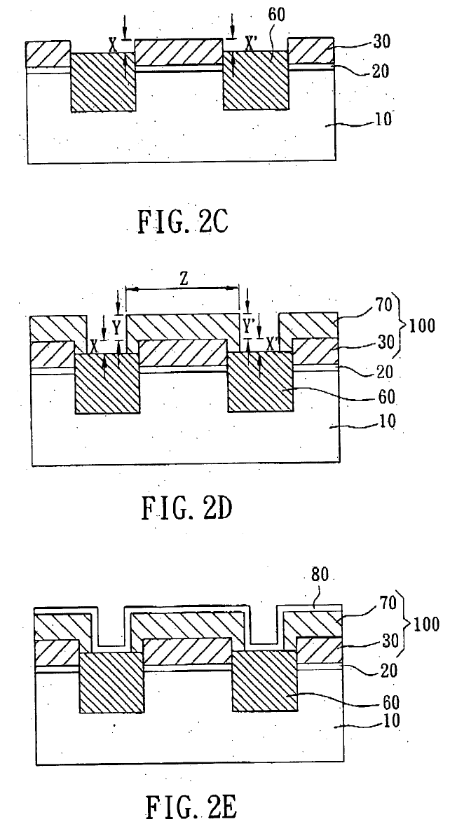

The present invention provides a flash memory structure having a T-shaped floating gate that has high capacitive coupling ratio. The following, as shown in FIG. 2A to FIG. 2E, is the method for fabricating the structure of the present invention, comprising the steps of:

(a) forming a coupling oxide layer 20, a buffered layer 30, and a sacrificial layer 40 in sequence on a semiconductor substrate 10; spin coating a photoresist on the sacrificial layer 40, defining a shallow trench isolation area 50 by exposing and developing with a mask, and then etching the coupling oxide layer 20, the buffered layer 30, and the sacrificial layer 40 which are not covered by the photoresist; etching the semiconductor substrate 10 by reactive ion etch (RIE) to form the shallow trench isolation area 50, as shown in FIG. 2A. In general, the components of the ion beam of RIE are SF₆ and Cl₂ mixed gas. The buffered layer 30 with a width of about 200 to 2500 Å is made of a material selected from the group consisting of polysilicon, silicide, amorphous silicon and the like.

(b) forming SiO₂ to fill the shallow trench isolation area 50 by Sub-Atmospherical Chemical Vapor Deposition (SACVD) or High Density Plasma Chemical Vapor Deposition (HDPCVD), and then forming a shallow trench isolation 60 (STI) by Chemical Mechanical Polishing (CMP) for planarization, in order to isolate each active area, as shown in FIG. 2B. The sacrificial layer 40 is as an etching stop layer in the CMP process, and is made of a material selected from the group consisting of silicon nitride and the like.

(c) removing the portion of shallow trench isolation 60 by buffer oxide etch (BOE) and then removing the sacrificial layer 40 so as to form a concave surface on the buffered layer 30 and a depth X as shown in FIG. 2C.

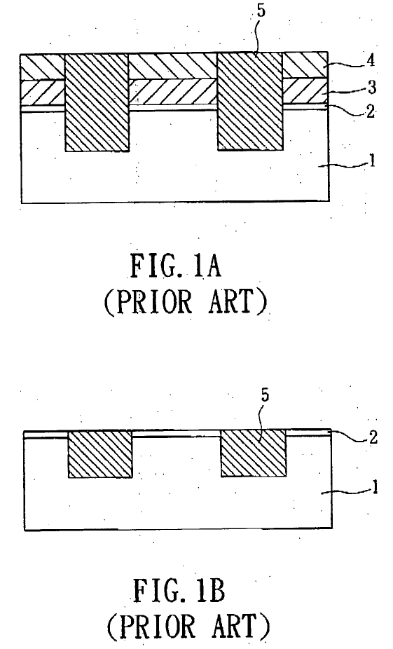

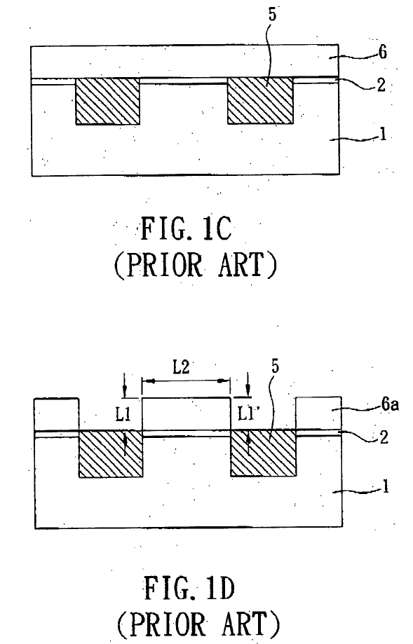

(d) depositing a conductive layer 70 and patterning the conductive layer 70 so that a T-shaped floating-gate 100 is formed from the conductive layer 70 and the buffered layer 30 so as to form a contacting area as well. As shown in FIG. 2D, a contacting area is formed on the conductive layer 70 and the buffered layer 30, which can be expressed as X+Y+Z+X′+Y′. Since the capacitive coupling capability of the floating gate is totally determined by the contacting area formed on the floating gate. Obviously, as seen in this case, the total length of X+Y+Z+X′+Y′ is much longer tan the total length of L1+L2+L1′ as shown in FIG. 1D, which means the T-shaped floating gate of the flash memory structure according to the present invention has higher capacitive coupling ratio than the one in prior art so as to increase the electrical property of flash memory. In practice, the conductive layer 70 with a width of about 300 to 3000 Å, and is made of a material selected from the group consisting of polysilicon, silicide, amorphous silicon and the like, will deliver the best electrical characteristic.

(e) depositing a thin dielectric layer 80 as an intermediate layer between T-shaped floating-gate 100 and control gate, as shown in FIG. 2E. The thin dielectric layer 80 with a width of about 50 to 300 Å is made of a material selected from nitride-oxide (NO), oxide-nitride-oxide (ONO) and the like.

In conclusion, the major advantage of the present invention is that, according to the description above, the contacting area of the floating gate is much bigger than the one in prior art, so it will increase the capacitive coupling ratio of stack-gate so as to increase the electrical property of the flash memory.

The present invention has been examined to be progressive and has great potential in commercial applications.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is

1. Method for fabricating a flash memory having a T-shaped floating gate, comprising the steps of:
(a) forming a coupling oxide layer, a buffered layer, and a sacrificial layer in sequence on a semiconductor substrate;
(b) forming shallow trench isolation (STI);
(c) removing the portion of STI and said sacrificial layer so as to form a concave surface on the STI and a proper depth;
(d) forming a conductive layer;
(e) patterning said conductive layer so that a T-shaped floating gate is formed from the conductive layer and the buffered layer.

2. The method for fabricating a flash memory having a T-shaped floating gate as recited in claim 1, further comprising a step (f) after step (e):
(f) forming a thin dielectric layer.

3. The method for fabricating a flash memory having a T-shaped floating gate as recited in claim 1, wherein said buffered layer and said conductive layer are made of a material selected from the group consisting of polysilicon, silicide and amorphous silicon.

4. The method for fabricating a flash memory having a T-shaped floating gate as recited in claim 1, wherein said sacrificial layer is silicon nitride.

5. The method for fabricating a flash memory having a T-shaped floating gate as recited in claim 1, wherein said buffered layer is formed to be 200 to 2500 Å in thickness.

6. The method for fabricating a flash memory having a T-shaped floating gate as recited in claim 1, wherein said conductive layer is formed to be 300 to 3000 Å in thickness.

7. The method for fabricating a flash memory having a T-shaped floating gate as recited in claim 2, wherein said thin dielectric layer is made of a material selected from the group consisting of nitride-oxide (NO) and oxide-nitride-oxide (ONO).

8. The method for fabricating a flash memory having a T-shaped floating gate as recited in claim 2, wherein said thin dielectric layer is formed to be 50 to 300 Å in thickness.

9. A structure of a flash memory having a T-shaped floating gate, comprising: a coupling oxide layer, a buffered layer and a conductive layer on a semiconductor substrate in sequence separated by shallow trench isolation (STI).

10. The structure of a flash memory having a T-shaped floating gate as recited in claim 9, wherein said buffered layer and said conductive layer are made of a material selected from the group consisting of polysilicon, silicide and amorphous silicon.

11. The structure of a flash memory having a T-shaped floating gate as recited in claim 9, wherein said buffered layer is formed to be 200 to is 2500 Å in thickness.

12. The structure of a flash memory having a T-shaped floating gate as recited in claim 9, wherein said conductive layer is formed to be 300 to 3000 Å in thickness.
